(19) United States
(12) Patent Application Publication
(10) Pub. No.: US 2017/0288158 A1
(43) Pub. Date: Oct. 5, 2017

(54) COMBINED SOLAR-RECHARGING THIN-FILM CHARGE-STORAGE DEVICE

(71) Applicant: Cambridge Display Technology, Ltd., Godmanchester (GB)

(72) Inventor: JONATHAN PILLOW, Hitchin (GB)

(73) Assignee: Cambridge Display Technology, Ltd., Godmanchester (GB)

(21) Appl. No.: 15/475,466

(22) Filed: Mar. 31, 2017

(30) Foreign Application Priority Data
Mar. 31, 2016 (GB) 1605400.9

(51) Int. Cl. H01L 51/42; H01L 51/44

(52) U.S. Cl. CPC H01L 51/424; H01L 51/441; H01L 51/448

(57) ABSTRACT

A combined solar recharging thin-film charge storage device and a method of its manufacture, wherein charge generation and storage are achieved within the same multilayer stack by providing a layer which functions as a photoactive layer and at the same time comprises ions towards which it is ion-permeable and separates physical contact between two electrodes. Accordingly, a simple device structure is provided which may be manufactured easily and cost-efficiently and which allows easy integration with other components.

### RELATED APPLICATIONS

This application claims the benefits under 35 U.S.C. §119(a)-(d) or 35 U.S.C. §365(b) of British application number GB1605400.9, filed Mar. 31, 2016, the entirety of which is incorporated herein by reference.

### FIELD OF INVENTION

This invention relates to a combined solar recharging thin-film charge storage device, wherein charge generation and storage are achieved within the same multilayer stack, and to a method of its manufacture.

### BACKGROUND OF THE INVENTION

A wide range of applications have been identified that require thin-film energy storage, and many of these also require the charge to be topped up by energy harvesting, rather than requiring a manual recharge process. Among energy harvesting methods, photovoltaic charging is widely known and available and uses one of the simplest forms of available energy, namely light. Many of the potential applications require charge to be available at times when light is not available (e.g. at night) or require electrical currents that are greater than can be provided by the available light intensity or by the area of photovoltaic cell, and in these cases some charge storage can be introduced. Trickle-charging a charge-storage device from the photovoltaic source can then smooth out the supply and demand and can also provide much greater current bursts for short amounts of time.

While the combination of energy harvesting and charge-storage is widely known, including with some thin-film systems, the solution usually requires separate modules for the two functions which must then be connected together, either by coupling separate devices on top of each other or side-by-side, e.g. by wiring connections, or in a monolithically integrated thin film device (see US 2015/0200311 A1, for example).

A preferred option, for its much greater simplicity and lower cost would be to create a single system that combines both charge generation and also charge storage mechanisms.

WO 2011/021982 A1 discloses integrated electrode architectures for energy generation and storage, wherein the energy charge storing unit and the energy converting unit (e.g. a photovoltaic cell) share a common electrode, which advantageously reduces the internal resistance between both units when compared to wired connections. However, this solution still requires a relatively large number of manufacturing steps and does not substantially reduce the material costs.

In view of the above, it remains desirable to provide a combined integrated photovoltaic charge-storage system which exhibits a simpler structure, may be produced cost-efficiently and in fewer steps, and may be easily integrated with other components.

### SUMMARY OF THE INVENTION

The present invention solves the above problems by providing a thin-film charge storage device that can be recharged by photovoltaic energy harvesting in a trickle-charge manner to enable sufficient charge to be accumulated for use under dark conditions or for higher-current applications. The invention thereby avoids the need for separate units for generating and storing the charge, with subsequent cost savings. This is enabled by the use of a photovoltaic charge-separation layer as the separator layer within the polymer charge-storage system that is also permeable to ion movement, thus enabling the battery to become charged.

Generally speaking, the present invention relates to a combined solar recharging thin-film charge storage device, comprising on a substrate, in the stated order: a first charge collector layer; an organic cathode; a photovoltaic separator layer; an organic anode; and a second charge collector layer; wherein the photovoltaic separator layer comprises ions towards which it is ion-permeable and separates physical contact between the organic anode and the organic cathode.

Method of manufacturing a combined solar recharging thin-film charge storage device, comprising: providing a photovoltaic separator layer between an organic cathode and an organic anode; wherein the photovoltaic separator layer comprises ions towards which it is ion-permeable and separates physical contact between the organic anode and the organic cathode.

Preferred embodiments of the device according to the present invention, other aspects of the invention, and advantages thereof are described in the following description and the claims. Further benefits will become apparent to the skilled artisan upon consideration of the invention disclosure.

### BRIEF DESCRIPTION OF DRAWINGS

FIG. 1 schematically illustrates the general architecture of a combined solar recharging thin-film charge storage device according to the present invention.

FIG. 2 schematically illustrates the processes during photovoltaic charge, taking into account the band-gaps and the HOMO/LUMO relationships between the photovoltaic separator layer and the organic electrodes.

FIG. 3 schematically illustrates a preferred embodiment of the present invention, wherein charge transport layers are provided between the photovoltaic separator layer and the organic electrodes.

### DETAILED DESCRIPTION OF THE INVENTION

### Combined Solar Recharging Thin-Film Charge Storage Device

In a first embodiment, the present invention relates to a combined solar recharging thin-film charge storage device. A basic exemplary configuration of the combined solar recharging thin-film charge storage device is illustrated in FIG. 1, which comprises: a substrate (1) (which is typically made of materials including plastics, glass, and metals); a first charge collector layer (2); an organic cathode (3); a photovoltaic separator layer (4) comprising ions towards which it is ion-permeable and separating physical contact between the organic cathode (3) and the organic anode (5). A second charge collector layer (6) is provided on the organic anode (5). The first and the second charge collector layers (2) and (6) allow the accumulated charge to pass through an external circuit (7). At least one side of the device must be at least partially light transmissive so that the photovoltaic separator layer can be excited by light.

It is to be noted that the device configuration of FIG. 1 is merely illustrative and does not intend to limit the present invention to the particular configuration. For instance, it will be understood that other layers may be present in the device, such as hole-transporting layers (HTL), electron blocking layers (EBL), hole-injecting layers (HIL), electron-injecting layers (EIL), exciton-blocking layer (XBL), spacer layers, connecting layers and hole-blocking layers (HBL), for example. In general, it is preferable that the photovoltaic separator layer is in direct contact with the organic cathode and the organic anode. Alternatively, it is preferable that a hole transport layer is interposed between and in direct contact with the organic cathode and the photovoltaic separator layer and/or a electron transport layer is interposed between and in direct contact with the organic anode and the photovoltaic separator layer.

As such, the photovoltaic separator layer fulfills multiple functions, as it acts as a photoactive layer, wherein excitons are generated upon photon absorption and as an ion-conductive separator between the electrodes. Furthermore, the photovoltaic separator layer functions as a medium bearing cationic and anionic species, which may move freely through the separator layer to the electrodes to counterbalance the electrical charge, i.e. as an electrolyte. Accordingly, the photovoltaic charge separation induced by the light may acts as an ion pump that can be used to store electrical energy until it is later released.

In a conventional open-circuit photovoltaic module, separated charges are quickly built up, and an electric field is generated which prevents any further charge separation and so that the photovoltaic module naturally exhibits low charge-storage capacitance. In contrast, in the combined solar recharging thin-film charge storage device of the present invention, the electric field encourages ions present in the photovoltaic separator layer to move through the device to counterbalance this field. The ion movement tends to negate the electrical charge imbalance and so opens up the possibility of further charge separation occurring, leading to an increase in capacitance of the system that is limited only by the availability of ions to be transferred and molecules (or equivalent) to accept the charges.

In preferred embodiments, the difference between the highest occupied molecular orbital (HOMO) level of the organic cathode material and the HOMO level of the photovoltaic separator layer is at least 0.5 eV, preferably from 0.5 to 1.0 eV; and/or the difference between the lowest unoccupied molecular orbital (LUMO) level of the organic anode material and the LUMO level of the photovoltaic separator layer is at least 0.5 eV, preferably from 0.5 to 1.0 eV. Most preferably, both the HOMO and LUMO levels are aligned in this way. Advantageously, said configuration allows efficient charge separation onto the organic anode and the organic cathode, respectively, since the energy barrier of at least 0.5 eV ensures that charge carriers transported to the organic electrodes do not return to the photovoltaic separator layer to recombine.

From the viewpoint of enhanced charge separation, it is preferable that the band-gap (i.e. the difference between the HOMO and the LUMO energy levels) of the photovoltaic separator layer is narrower than each of the band-gaps of the organic anode material and the organic cathode material.

Preferably, the organic anode material has a band-gap of at least 3 eV and/or the organic cathode material has a band-gap of at least 3 eV. It is likewise preferable that the photovoltaic separator layer has a band-gap of between 2 eV and 3 eV, more preferably between 2.3 and 2.7 eV.

The HOMO/LUMO energy levels as well as the band-gap may be determined by methods known to the skilled artisan, for example by using standard methods of cyclic voltammetry.

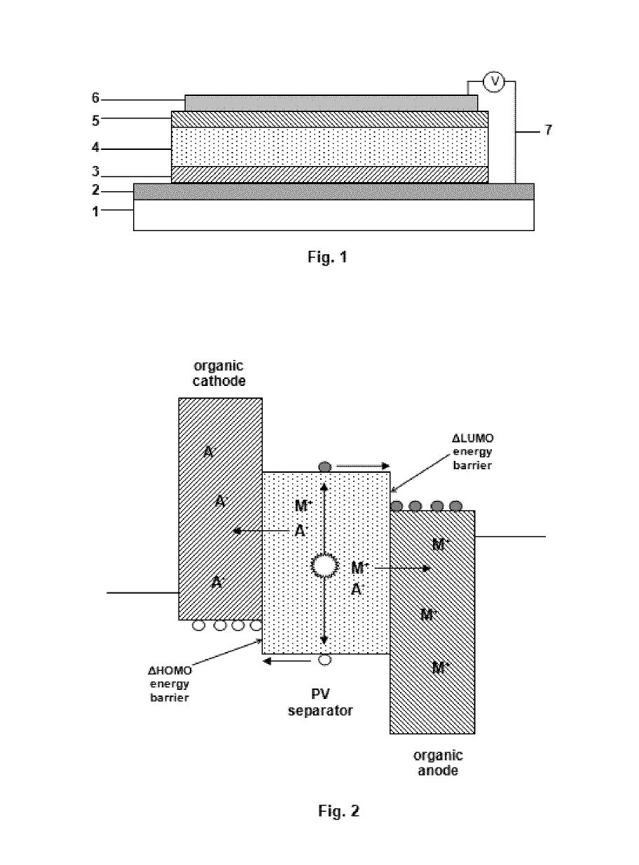

A further illustration of the processes occurring during photovoltaic charge is shown in FIG. 2. The photoactive material contained in the photovoltaic separator layer effects the generation of excitons (i.e. hole/electron-pairs) upon photon absorption (central band). Since the band-gap of the photovoltaic separator layer is narrower than that of the charge acceptor materials, it is ensured that the created excitons are maintained within the photovoltaic separator layer for enhanced charge separation. Charge separation onto the organic cathode (left) and organic anode materials (right) are enabled by the drop in energy between the HOMOs (for the cathode) and the LUMOs (for the anode), so that the charges cannot return to the photovoltaic separator layer and recombine. The photovoltaic separator layer may contain all the ions required for the device, with the anions (A⁻) and cations (M⁺) flowing separately into the charge storage layers as they are charged up. Once a few charges have separated—as in any standard photovoltaic process—the internal field will start to slowly move the ions that permeate the separator across, negating this field. In this way, charges can steadily accumulate and the battery becomes charged. Once sufficient charge has been accumulated, the battery can be discharged in the same way as a standard battery-supercapacitor hybrid, by enabling the charges to pass onto the current collectors and thence into the external circuit, while the ions return to their starting positions to restore electrical neutrality.

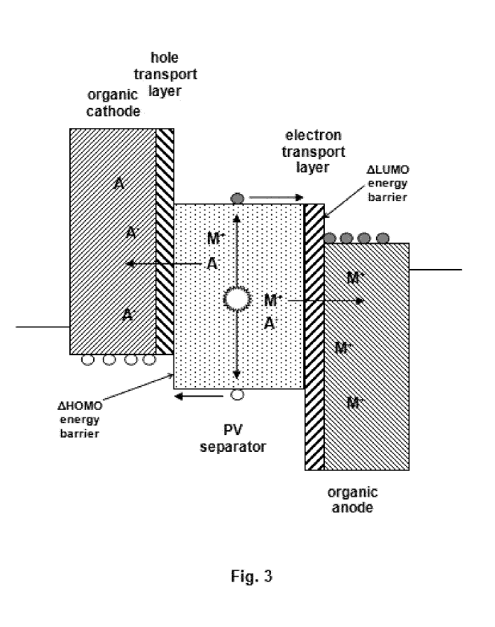

In a preferred embodiment of the present invention, a hole transport layer is interposed between and preferably in direct contact with the organic cathode and the photovoltaic separator layer and/or a electron transport layer is interposed between and preferably in direct contact with the organic anode and the photovoltaic separator layer. Materials for the hole transport and electron transport layers are not particularly limited and may be suitably selected from conventional charge transport materials known in the art. An example of a configuration wherein both of these charge transport layers are present is illustrated in FIG. 3. In general, this embodiment is advantageous since it allows to use materials for the photovoltaic separator layer which have a narrower bandgap when compared to the embodiment of FIG. 2, since the energy barriers that ensure that charge carriers transported to the organic electrodes do not return to the photovoltaic separator layer to recombine may be formed at the interface between the charge transport layers and the organic electrodes, so that in this embodiment the alignment of the HOMO level of the photovoltaic separator layer to the HOMO of the organic cathode and the alignment of the LUMO level of the photovoltaic separator layer to the LUMO of the organic electrode is less critical. As it will be readily understood, said configuration also allows a wider range of organic electrode materials to be used, so that in principle the band-gap of the organic anode material may be less than 3 eV, the band-gap of the organic cathode material may be less than 3 eV and/or the band-gap of the photovoltaic separator layer may be less than 2 eV as long as the HOMO and LUMO levels are aligned to form charge recombination barriers. In this case, it is preferable that the band-gap of the organic anode and/or cathode material is at least 2 eV, and that the band-gap of the photovoltaic separator layer is in the range of from 1.3 to 3.0 eV, more preferably 1.5 to 3.0.

A variety of materials may be used in this device, if they are sufficiently stable to the charges involved and ideally exhibit the desired energy levels.

Materials for the organic anode and cathode may be suitably selected by the skilled artisan and include n-type organic semiconductors and p-type organic semiconductors, respectively.

As examples of the n-type organic semiconductor material that may be used as organic anode material, polymers based on heterocyclic repeating units (such as triazine derivatives (e.g. 1,3,5-triazine derivatives), azafluorene derivatives and benzothiadiazole derivatives); n-type conjugated polymers, and carbonyl-based polymers (such as fluorenone derivatives) may be mentioned. Preferably, the organic anode material comprises triazine derivatives.

The p-type organic semiconductor material that may be used as organic anode material may be selected appropriately from the group of p-phenylenevinylenebased conjugated polymers, fluorene-based conjugated polymers, carbazole-based conjugated polymers, thiophene-based conjugated polymers, poly(aryleneethynylene)s, triarylamine-based small molecules or polymers, phenothiazine-based polymers, and porphyrin-based polymers for example. In a preferred embodiment, the organic anode material comprises triarylamine-based small molecules or polymers.

In principle, the photovoltaic separator layer may be composed of a single material or of a blend of two or more materials. In case of a blend of multiple materials, it is preferred that the combined band-gap is between 2 eV and 3 eV, more preferably between 2.3 and 2.7 eV, further preferably between 2.4 to 2.6 eV. If charge transport layers are interposed between the photovoltaic separator layer and the organic electrodes, the combined band-gap is preferably between 1.3 eV and 3 eV.

As with conventional organic solar cells, the photovoltaic effect may originate in a single photoactive layer, or in a bilayer, graded, bulk, or diffuse p-n heterojunction comprised in the photovoltaic separator layer. Therefore, the photovoltaic separator layer may consist of a single homogeneous layer or of multiple distinct sub-layers, provided that the HOMO and LUMO energy levels are aligned as set out above in order to ensure efficient charge separation. The photovoltaic separator layer may include p-type organic semiconductors and n-type organic semiconductors which may be appropriately selected from standard electron donating and electron accepting materials that are known to the person skilled in the art, which fulfill the above requirements regarding the HOMO and LUMO energy levels.

The photovoltaic separator layer may consist of a single phase or of multiple phases provided that the ion-conducting phase is continuous and connects with the adjacent charge transporting or organic electrode layers. As a preferred example of a multiple phase photovoltaic separator layer, a three phase-separator comprising p-type conductive material, n-type conductive material and an ion-conductive phase that may be a solid (such as ion-conductive homo- and co-polymers) or a liquid (e.g. electrolyte) may be mentioned.

The photovoltaic separator layer may also exhibit a pore structure which enables saturation with an electrolyte in order to provide ionic conductivity.

Preferably, the photovoltaic separator layer exhibits an ion conductivity of at least 10⁻⁶Ω⁻¹·cm⁻¹, more preferably at least 10⁻⁵Ω⁻¹·cm⁻¹ with respect to the ions used. More preferably, the organic cathode and/or the organic anode likewise exhibit an ion conductivity in the given range. The ionic conductivity referred to herein may be measured using traditional impedance analysis techniques for measuring ac-conductivity, for example, as described in British Library Cataloguing in Publication Data Electrochemistry (Chemical Society, Specialist periodical reports), The Chemical Society, Burlington House, London WIVOBN, Vol. 7 (1980); West, A. R., Solid State Chemistry and Its Applications, John Wiley & Sons Ltd., (1984); and R. D. Armstrong, T. Dickinson, P. M. Willis, Electroanalytical Chemistry and Interfacial Electrochemistry, Vol. 53, 389 (1974).

The photovoltaic separator layer, the organic cathode and/or the organic anode may comprise ion-conductive homo- and co-polymers selected, for example, from: polyethers (including e.g. poly(ethylene oxide) (PEO) (also referred to as polyethylene glycol (PEG)) or polypropylene oxide (PPO)); polysiloxanes (including e.g. block copolymers of dimethyl siloxane and ethylene oxide, urethane-crosslinked networks of poly(dimethyl siloxane-graft-ethylene oxide), and copolymers based on poly(methyl hydrosiloxane), poly(ethylene glycol)monomethyl ether and poly(ethylene glycol)); poly(meth)acrylates (including e.g. poly[(methyl)methacrylate], poly(methoxy ethoxy ethyl methacrylate) (polyMEEMA) and poly[(ω-carboxy) oligooxyethylene methacrylate]); polyphosphazenes (e.g. methoxy ethoxy ethoxy polyphosphazene (MEEP)); poly(vinyl pyrrolidines); poly(crown ethers); itaconate-based (co-)polymers (including e.g. poly[diethoxy(3)methyl itaconate] and poly(di-poly(propylene glycol)itaconate)); succinate-based (co-)polymers (e.g. poly(ethylene succinate)); adipate-based (co-)polymers (e.g. poly(ethylene adipate)); cellulose acetates; poly(vinyl alcohols); poly(ethylene imines); poly(alkylene sulphides); poly(propiolactones); poly(vinyl methyl ketones); poly(hexamethylenevinylenes); poly(styrenes); poly(2-ethyl-2-oxazoline); polyacrylonitrile; polybutadiene; polyisoprene; derivatives of these polymers; and blends thereof.

In a preferred embodiment, the organic cathode, the photovoltaic separator layer and/or the organic anode comprise polyethylene glycol (PEG) based ion-transport enhancing materials. More preferably, at least the photovoltaic separator layer comprises polyethylene glycol (PEG) based ion-transport enhancing materials.

For each of the organic cathode, the photovoltaic separator layer and the organic anode, the materials can take the form of solid polymer films, films that include ion-transport enhancing materials such as PEG chains, films that contain a high proportion of ions (potentially with solvent too) including as a gel, and films that have a degree of 3D patterning for example by being in the form of particles or fibres or other patterns.

The material used for the first and second charge collector layers is not particularly limited as long as it exhibits sufficient electrical conductivity and is capable of collecting the holes and electrons accumulated in the organic cathode and organic anode, respectively.

The first charge collector layer is preferably a hole accepting layer. Although not necessary, said layer may also serve to block electrons. As examples of suitable materials for the first charge collector layer, conductive polymers such as poly(3,4-ethylenedioxythiophene) poly(styrenesulfonate) (PEDOT:PSS) or other doped polymers based on e.g. polyaniline or polyacetylene, or inorganic materials, such as a metal oxides (which may include molybdenum oxide (MOₓ), tungsten oxide (WOₓ), vanadium oxide (VOₓ), nickel oxide NiO, or cuprous oxide Cu₂O, for example), metals (including stainless steel and gold, for example) or carbon may be mentioned.

The second charge collector layer is preferably an electron accepting layer. Although not necessary, said layer may also serve to block holes. As examples of suitable materials for the second charge collector layer, inorganic materials such as lithium fluoride (LiF) or other alkali metal fluorides, oxides, or carbonates, metal oxides (MOx) selected from titania (TiO₂), zinc oxide, tin oxide, niobium oxide, zirconium oxide, compound oxides (e.g. niobium titanium oxide), metals (including copper, gold, zinc or stainless steel, for example); organic polymers and hybrid materials may be mentioned. Exemplary compounds of the latter are e.g. disclosed in S. Lattante, Electronics 2014, 3, 132-164.

The thicknesses of the layers comprised in the combined solar recharging thin-film charge storage device of the present invention are not particularly limited and may be appropriately selected in dependence of the optoelectronic and mechanical properties of the materials used. While the thickness of the first charge collector layer, the organic cathode, the organic anode, and the second charge collector layer will be typically in the range of 1 nm to 1 μm, preferably 10 to 500 nm per layer, the thickness of the photovoltaic separator layer may exceed this range, e.g. if the presence of relatively high total amounts of ions is desired.

Accordingly, this combined system provides substantially lower manufacture and material costs as it exhibits a simpler structure compared to more complicated systems that involve separate PV and energy storage units, particularly since the same materials are likely to be included in both separate systems along with many duplications and other layers that are not needed in this invention.

### Method of Manufacturing the Combined Solar Recharging Thin-Film Charge Storage Device

In a second embodiment, the present invention relates to a method of manufacturing a combined solar recharging thin-film charge storage device, comprising providing a photovoltaic separator layer between an organic cathode and an organic anode, wherein the photovoltaic separator layer comprises ions towards which it is ion-permeable and separates physical contact between the organic anode and the organic cathode.

Preferably, the combined solar recharging thin-film charge storage device produced by this method exhibits the properties set out above in conjunction with the first embodiment.

Advantageously, providing a photovoltaic separator layer comprising ions towards which it is ion-permeable so as to separate physical contact between the organic anode and the organic cathode eliminates the need of requiring separate multilayer structures for the charge storage and energy harvesting modules.

Each of the layers comprised in the combined solar recharging thin-film charge storage device of the present invention, including the photovoltaic separator layer, may be provided by conventional deposition, coating and lamination techniques known in the art, which may be appropriately selected by the skilled artisan in dependence of the material used. While not being limited thereto, exemplary coating and deposition techniques include thermal deposition, vacuum deposition, laser deposition, screen printing, printing, imprinting, spin casting, dipping, ink-jetting, roll coating, flow coating, drop casting, spray coating, and/or roll printing.

Once given the above disclosure, many other features, modifications, and improvements will become apparent to the skilled artisan.

### REFERENCE NUMERALS

1—substrate

2—first charge collector layer

3—organic cathode

4—photovoltaic separator layer

5—organic anode

6—second charge collector layer

7—contact/external circuit

1. A combined solar recharging thin-film charge storage device, comprising on a substrate, in the stated order:
a first charge collector layer;
an organic cathode;
a photovoltaic separator layer;
an organic anode; and
a second charge collector layer;
wherein the photovoltaic separator layer comprises ions towards which it is ion-permeable and separates physical contact between the organic anode and the organic cathode.

2. The combined solar recharging thin-film charge storage device according to claim 1, wherein the photovoltaic separator layer is in direct contact with the organic cathode and the organic anode.

3. The combined solar recharging thin-film charge storage device according to claim 1, further comprising a hole transport layer interposed between and preferably in direct contact with the organic cathode and the photovoltaic separator layer and/or a electron transport layer interposed between and in direct contact with the organic anode and the photovoltaic separator layer.

4. The combined solar recharging thin-film charge storage device according to claim 1, wherein the difference between the HOMO level of the organic cathode material and the HOMO level of the photovoltaic separator layer is at least 0.5 eV and/or wherein the difference between the LUMO level of the organic anode material and the LUMO level of the photovoltaic separator layer is at least 0.5 eV.

5. The combined solar recharging thin-film charge storage device according to claim 3, wherein the difference between the HOMO level of the hole transport layer and the HOMO level of the photovoltaic separator layer is at least 0.5 eV and/or wherein the difference between the LUMO level of the electron and the LUMO level of the photovoltaic separator layer is at least 0.5 eV.

6. The combined solar recharging thin-film charge storage device according to claim 1, wherein the band-gap of the photovoltaic separator layer is narrower than each of the band-gaps of the organic anode material and the organic cathode material.

7. The combined solar recharging thin-film charge storage device according to claim 1, wherein the organic anode material has a band-gap of at least 3 eV.

8. The combined solar recharging thin-film charge storage device according to claim 1, wherein the organic cathode material has a band-gap of at least 3 eV.

9. The combined solar recharging thin-film charge storage device according to claim 1, wherein the photovoltaic separator layer has a band-gap of between 2 eV and 3 eV, preferably between 2.3 and 2.7 eV.

10. The combined solar recharging thin-film charge storage device according to claim 1, wherein the organic cathode material is a p-type organic semiconductor material selected from the group of triarylamine-based small molecules or polymers.

11. The combined solar recharging thin-film charge storage device according to claim 1, wherein the organic anode material is an n-type organic semiconductor material selected from the group of triazine derivatives.

12. The combined solar recharging thin-film charge storage device according to claim 1, wherein the photovoltaic separator layer comprises polyethylene glycol (PEG) based ion-transport enhancing materials.

13. The combined solar recharging thin-film charge storage device according to claim 1, wherein the photovoltaic separator layer exhibits an ion conductivity of at least 10⁻⁶Ω⁻¹·cm⁻¹.

14. The combined solar recharging thin-film charge storage device according to claim 1, wherein the photovoltaic separator layer comprises p-type conductive material, n-type conductive material and an ion-conductive phase which is continuous and connects with layers adjacent to the photovoltaic separator layer.

15. A method of manufacturing a combined solar recharging thin-film charge storage device, the method comprising
providing a photovoltaic separator layer between an organic cathode and an organic anode,
wherein the photovoltaic separator layer comprises ions towards which it is ion-permeable and separates physical contact between the organic anode and the organic cathode.
